(19) United States
(12) Patent Application Publication
(10) Pub. No.: US 2024/0120896 A1
(43) Pub. Date: Apr. 11, 2024

(54) DIFFERENTIAL AMPLIFIER CIRCUIT

(71) Applicant: ROHM CO., LTD., Kyoto-shi (JP)

(72) Inventor: Yuma ITO, Kyoto-shi (JP)

(21) Appl. No.: 18/480,638

(22) Filed: Oct. 4, 2023

(30) Foreign Application Priority Data
Oct. 7, 2022 (JP) 2022-162469

(51) Int. Cl. H03F 3/45; H04R 3/04

(52) U.S. Cl. CPC H03F 3/45475; H04R 3/04; H03F 2200/03; H03F 2200/393; H03F 2200/471

(57) ABSTRACT

The present disclosure provides a differential amplifier circuit for actuating a speaker. The differential amplifier circuit includes: a first amplifier configured to amplify a positive signal of a differential signal; a second amplifier configured to amplify a negative signal of the differential signal; and a determination circuit configured to monitor the positive signal and the negative signal. The determination circuit includes: a comparator; a selection circuit configured to selectively supply a first detection signal corresponding to the positive signal and a second detection signal corresponding to the negative signal to a first input of the comparator by time division; a voltage source configured to supply a plurality of threshold voltages to a second input of the comparator by time division; and a determination unit configured to determine a state of the differential signal based on an output of the comparator.

### CROSS REFERENCE TO RELATED APPLICATIONS

The present invention claims priority under 35 U.S.C. § 119 to Japanese Application, 2022-162469, filed on Oct. 7, 2022, the entire contents of which being incorporated herein by reference.

### TECHNICAL FIELD

The present disclosure relates to a differential amplifier circuit for audio use.

### BACKGROUND

A speaker may be actuated by means of a bridge-tied load (BTL). An amplifier circuit of the BTL means includes an amplifier that amplifies a positive input signal of an audio signal, and an amplifier that amplifies a negative input signal.

### BRIEF DESCRIPTION OF THE DRAWINGS

FIG. 1 is a diagram of an audio system according to an embodiment.

FIG. 2 is a waveform diagram illustrating operations of an amplifier circuit.

FIG. 3 is a circuit diagram of a determination circuit of a comparison technique.

FIG. 4 is a circuit diagram of a configuration example of a determination circuit.

### DETAILED DESCRIPTION OF THE EMBODIMENTS

### (Summary of Embodiments)

A summary of several exemplary embodiments of the disclosure is given below. The summary serves as the preamble of the detailed description to be given shortly and aims at providing fundamental understanding of the embodiments by describing several concepts of one or more embodiments in brief. It should be noted that the summary is not to be construed as limitations to the breadth of the application or disclosure. The summary is not a comprehensive summary of all conceivable embodiments, nor does it intend to specify important elements of all embodiments or to define the scope of a part of or all aspects. For the sake of better description, “one embodiment” sometimes refers to one embodiment (an implementation example or a variation example) or multiple embodiments (implementation examples or variation examples) disclosed in the disclosure.

In one embodiment, a differential amplifier circuit is for actuating a speaker. The differential amplifier circuit includes a first amplifier configured to amplify a positive signal of a differential signal, a second amplifier configured to amplify a negative signal of the differential signal, and a determination circuit configured to monitor the positive signal and the negative signal. The determination circuit includes a comparator, a selection circuit configured to selectively supply a first detection signal corresponding to the positive signal and a second detection signal corresponding to the negative signal to a first input of the comparator by time division, a voltage source configured to supply a plurality of threshold voltages to a second input of the comparator by time division, and a determination unit configured to determine a state of the differential signal based on an output of the comparator.

According to the configuration above, a voltage level of each of the positive signal and the negative signal of the differential signal is determined by time division by using one comparator, so that the state of the differential signal can be determined by a simple configuration.

In one embodiment, the plurality of threshold voltages are in a number of two.

In one embodiment, each of the two threshold voltages is selectable from a plurality of voltage levels.

In one embodiment, the selection circuit may include a first voltage dividing circuit configured to divide the positive signal to generate the first detection signal, and a second voltage dividing circuit configured to divide the negative signal to generate the second detection signal.

In one embodiment, a voltage dividing ratio of the first voltage dividing circuit and a voltage dividing ratio of the second voltage dividing circuit are switchable.

In one embodiment, the determination unit may detect a state in which the differential signal contains a DC component.

In one embodiment, the determination unit may detect a state in which the differential signal is an excessive input.

In one embodiment, the determination unit may detect an amplitude of the differential signal.

In one embodiment, the differential amplifier circuit may be monolithically integrated on a semiconductor substrate. The so-called “monolithically integrated” includes a situation in which all constituting elements of a circuit are formed on a semiconductor substrate, or a situation in which main constituting elements of a circuit are integrated. In order to adjust circuit constants, a part of resistors or capacitors may be arranged outside the semiconductor substrate. By integrating circuits on one chip, the circuit area can be reduced, and characteristics of circuit elements can also be kept uniform.

### EMBODIMENTS

Details of preferred embodiments are given with the accompanying drawings below. The same or equivalent constituent elements, parts and processes in the accompanying drawings are represented by the same denotations, and repeated description is omitted as appropriate. Moreover, the embodiments are illustrative of and are not restrictive of the disclosure. All features and combinations thereof described in the embodiments are not necessarily intrinsic characteristics of the disclosure.

In the description of the application, an expression “a state of component A connected to component B” includes, in addition to a situation where component A and component B are directly connected, a situation where component A is indirectly connected to component B via another component, and the indirect connection does not result in substantial influences on their electrical connection or does not impair functions or effects exerted by their combination.

Similarly, an expression “a state of component C connected (arranged) between component A and component B” also includes, in addition to a situation where component A and component C, or component B and component C are directly connected, an indirect connection via another component, and the indirect connection does not result in substantial influences on their electrical connection or does not impair functions or effects exerted by their combination.

Moreover, in the description, denotations assigned to electrical signals such as voltage signals and current signals, and circuit elements such as resistors, capacitors and inductors are expressed with respective voltage values, current values, or circuit constants (resistance values, capacitance values and inductance values) as needed.

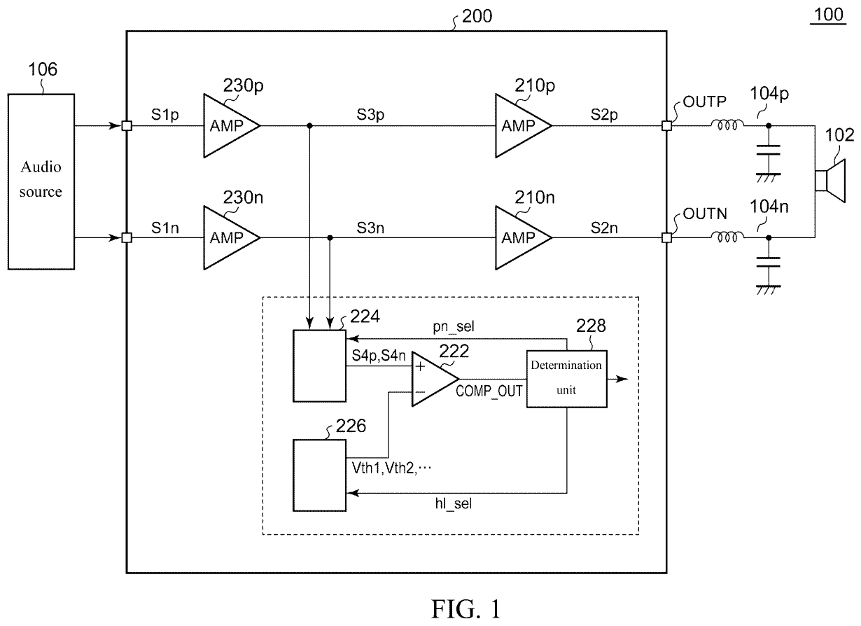

FIG. 1 shows a diagram of an audio system 100 according to an embodiment. The audio system 100 includes a speaker 102, a filter 104, an audio source 106 and an amplifier circuit 200.

The audio source 106 supplies a differential audio signal S1 to the amplifier circuit 200. In the description below, a positive signal of the differential signal is denoted with a subscript p, and a negative signal is denoted with a subscript n.

The amplifier circuit 200 amplifies the differential audio signal S1 and actuates the speaker 102. The audio system 100 is constructed in the form of BTL, and the amplifier circuit 200 outputs an amplified differential audio signal S2 from a positive output OUTP and a negative output OUTN. A positive signal S2p of the differential audio signal S2 is supplied to one end of the speaker 102 via a filter 104p, and a negative signal S2n of the differential audio signal S2 is supplied to the other end of the speaker 102 via a filter 104n.

The amplifier circuit 200 is a functional integrated circuit (IC) monolithically integrated on a semiconductor substrate and includes a first main amplifier (also referred to as a power amplifier) 210p, a second main amplifier 210n, a determination circuit 220, a first pre-amplifier 230p and a second pre-amplifier 230n.

The first pre-amplifier 230p amplifies a positive signal S1p of the differential audio signal S1. The second pre-amplifier 230n amplifies a negative signal S In of the differential audio signal S1.

The first main amplifier 210b actuates the speaker 102 based on a signal S3p amplified by the first pre-amplifier 230p, and the second main amplifier 210n actuates the speaker 102 based on a signal S3n amplified by the second pre-amplifier 230n.

The first main amplifier 210p and the second main amplifier 210n are class-D amplifiers. Each of the first main amplifier 210p and the second main amplifier 210n may include a pulse width modulator, a driver circuit, and an output stage.

The determination circuit 220 monitors the positive signal S3p and the negative signal S3n of a differential signal S3.

The determination circuit 220 includes a comparator 222, a selection circuit 224, a voltage source 226 and a determination unit 228.

The selection circuit 224 receives the positive signal S3p and the negative signal S3n. The selection circuit 224 selectively supplies a first detection signal S4p corresponding to the positive signal S3p and a second detection signal S4n corresponding to the negative signal S3n to a first input (for example, a non-inverting input) of the comparator 222 by time division.

The voltage source 226 supplies a plurality of threshold voltages Vth1, Vth2, or the like to a second input (for example, an inverting input) of the comparator 222 by time division.

The determination unit 228 determines a state of the differential signal S3 based on an output COMP_OUT of the comparator 222. The determination unit 228 also functions as a sequencer that switches states of the selection circuit 224 and the voltage source 226.

If the differential signal S3 contains a direct-current (DC) component, a DC current continuously flows through the speaker 102, causing a concern for reduced reliability of the speaker 102. In one embodiment, the determination unit 220 determines whether the differential signal S3 contains a DC component.

The voltage source 226 outputs the first threshold voltage Vth1 and the second threshold voltage Vth2 by time division. The first threshold voltage Vth1 is determined to be higher than a common voltage Vc of the positive signal S3p and the negative signal S3n, and the second threshold voltage Vth2 is determined to be lower than the common voltage Vc of the positive signal S3p and the negative signal S3n.

For example, the common voltage Vc can be determined to be 0.5 times of a power supply voltage Vcc. In this case, the first threshold voltage Vth1 can be determined to be 0.6×Vcc, and the second threshold voltage Vth2 can be determined to be 0.4×Vcc. Alternatively, the first threshold voltage Vth1 can be determined to be 0.7×Vcc, and the second threshold voltage Vth2 can be determined to be 0.3×Vcc.

For example, the determination unit 228 sequentially repeats four states ϕ 1 to ϕ 4 by time division. Moreover, sequences of state migration are not specifically defined.

First state ϕ 1

The selection circuit 224 outputs the first detection signal S4p corresponding to the positive signal S3p. The voltage source 226 outputs the first threshold voltage Vth1.

Second state ϕ 2

The selection circuit 224 outputs the first detection signal S4p corresponding to the positive signal S3p. The voltage source 226 outputs the second threshold voltage Vth2.

Third state ϕ 3

The selection circuit 224 outputs the second detection signal S4n corresponding to the negative signal S3n. The voltage source 226 outputs the first threshold voltage Vth1.

Fourth state ϕ 4

The selection circuit 224 outputs the first detection signal S4p corresponding to the positive signal S3p. The voltage source 226 outputs the second threshold voltage Vth2.

The determination unit 228 supplies a control signal pn_sel to the selection circuit 224. The control signal pn_sel is at a first level (for example, high) in the first state ϕ 1 and the second state ϕ 2, and is at a second level (for example, low) in the third state ϕ 3 and the fourth state ϕ 4. The selection circuit 224 outputs the first detection signal S4p corresponding to the positive signal S3p when the control signal pn_sel is at a first level, and outputs the second detection signal S4n corresponding to the negative signal S3n when the control signal pn_sel is at a second level.

Moreover, the determination unit 228 supplies a control signal h1_sel to the voltage source 226. The control signal h1_sel is at a first level (for example, high) in the first state ϕ 1 and the third state ϕ 3, and is at a second level (for example, low) in the second state ϕ 2 and the fourth state ϕ 4. The voltage source 226 outputs the first threshold voltage Vth1 when the control signal h1_sel is at a first level, and outputs the second threshold voltage Vth2 when the control signal h1_sel is at a second level.

A switching frequency (time division frequency) of the states ϕ 1 to ϕ 4 is preferably determined to be more than twice a maximum frequency (20 kHz) of the audio signal, that is, more than 40 kHz.

The configuration of the amplifier circuit 200 is as described above. The operation of the amplifier circuit 200 is described below.

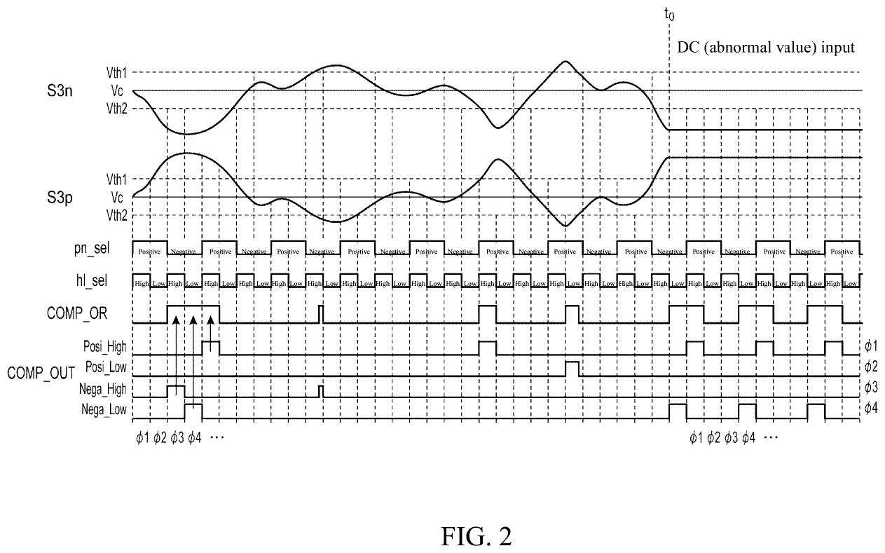

FIG. 2 shows a waveform diagram illustrating operations of the amplifier circuit 200. The determination unit 228 processes the output COMP_OUT of the comparator 222 by time division by means of digital system processing and detects for an anomaly based on a detection result in the four states ϕ 1 to ϕ 4.

In the first state ϕ 1, the first detection signal S4p and the first threshold voltage Vth1 are compared by the comparator 222. Posi_High, Posi_Low, Nega_High and Nega_Low represent the outputs COMP_OUT of the comparator 222 in respective intervals of the states ϕ 1 to ϕ 4. Moreover, Posi_Low and Nega_Low have logic values that invert the outputs COMP_OUT of the comparator 222.

Determination information COMP_OR is a logical sum of Posi_High, Posi_Low, Nega_High and Nega_Low. Posi_High, Posi_Low, Nega_High, Nega_Low and COMP_OR are internal signals of the determination unit 228.

It is a normal state before a timing t0. In the normal state, the output COMP_OUT of the comparator 222 changes randomly.

It is set that the DC input is abnormal when the differential signal S3 containing a DC component occurs at the timing t0. In this case, the output COMP_OUT of the comparator 222 is continuously asserted in at least one of the states ϕ 1 to ϕ 4. In the example in FIG. 2, in the first state ϕ 1 and the fourth state ϕ 4, the determination information COMP_OR is continuously high in each cycle. If the state above is detected, the determination unit 228 determines that the DC input is abnormal.

The operation of the amplifier circuit 200 is as described above. According to the amplifier circuit 200, the voltage level of each of the positive signal S3p and the negative signal S3n of the differential signal S3 is determined by time division by using one comparator, so that the state of the differential signal can be determined by a simple configuration.

The advantages of the amplifier circuit 200 in FIG. 1 can become more apparent in comparison with a comparison technique.

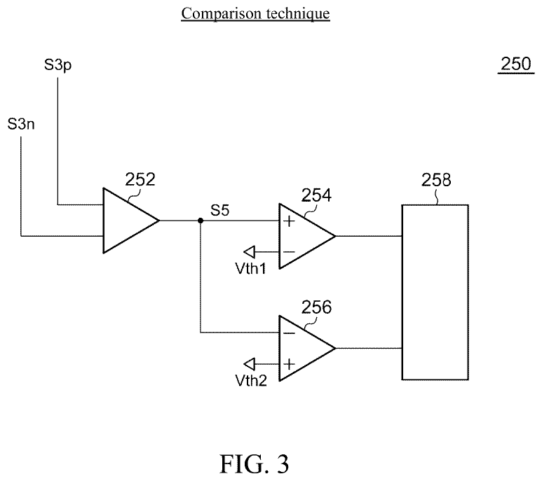

FIG. 3 shows a circuit diagram of a determination circuit 250 of a comparison technique. The determination circuit 250 includes an amplifier 252, comparators 254 and 256 and a determination unit 258. The amplifier 252 converts the differential signal S3 into a single ended signal S5. The comparator 254 compares the single ended signal S5 with the first threshold voltage Vth1, and the comparator 256 compares the single ended signal S5 with the second threshold voltage Vth2. The determination unit 258 determines that the DC input is abnormal based on outputs of the comparators 254 and 256.

When it is detected that the DC input is abnormal, the amplifier circuit 200 can perform circuit protection. More specifically, when amplifier circuit 200 can set outputs OUTP and OUTN to high impedance (or setting the two to low), and stop supplying power to a load, that is, to the speaker 102.

Now that the determination circuit 250 of the comparison technique needs the amplifier 252 as well as two comparators, resulting in greater circuit area and power consumption. On the contrary, in the determination circuit 220 of the embodiment, both circuit area and power consumption can be reduced.

The disclosure can be grasped by the block diagram or circuit diagram of FIG. 1, and various devices and methods derived from the disclosure related thereto are not limited to being specific configurations. To help better and more clearly understand the essentials and operations of the disclosure or the application but not to narrow scope of the disclosure, more specific configuration examples and embodiments are described below.

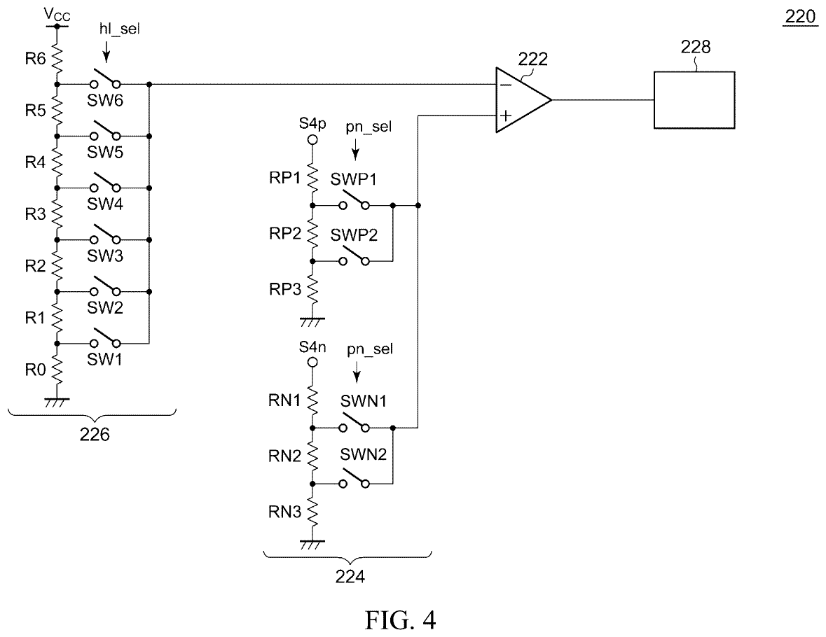

FIG. 4 shows a circuit diagram of a configuration example of the determination circuit 220. The voltage source 226 is a resistor string type digital-to-analog converter (DAC) and includes a plurality of resistors R0 to R6 and switches SW1 to SW6. The voltage source 226 can set the first threshold voltage Vth1 according to an amplitude level of a detection signal S4, and in the first state ϕ 1 and the third state ϕ 3, any of the switches SW4 to SW6 is turned on based on the control signal h1_sel. The threshold voltage Vth1 decreases when the switch SW4 is selected, and the threshold voltage Vth1 increases when the switch SW6 is selected.

Similarly, the voltage source 226 can set the second threshold voltage Vth2 according to the amplitude level of the detection signal S4, and in the second state ϕ 2 and the fourth state ϕ 4, any of the switches SW1 to SW3 is turned on based on the control signal h1_sel. The threshold voltage Vth2 decreases when the switch SW1 is selected, and the threshold voltage Vth2 increases when the switch SW3 is selected.

The selection circuit 224 includes a first voltage dividing circuit 224p and a second voltage dividing circuit 224n. The first voltage dividing circuit 224p divides the positive signal S3p to generate the first detection signal S4p. The second voltage dividing circuit 224n divides the negative signal S3n to generate the second detection signal S4n.

A voltage dividing ratio of the first voltage dividing circuit 224p and a voltage dividing ratio of the second voltage dividing circuit 224n are switchable. More specifically, the first voltage dividing circuit 224p includes a plurality of resistors RP1 to RP3, and a plurality of switches SWP1 and SWP2. In the first state ϕ 1 and the second state ϕ 2, a specified switch between the plurality of switches SWP1 and SWP2 is turned on according to the control signal pn_sel.

Similarly, the second voltage dividing circuit 224n includes a plurality of resistors RN1 to RN3, and a plurality of switches SWN1 and SWN2. In the third state ϕ 3 and the fourth state ϕ 4, a specified switch between the plurality of switches SWN1 and SWN2 is turned on according to the control signal pn_sel.

The configuration of the determination circuit 220 is as described above.

Next, a variation example is described below.

### (Variation Example 1)

The determination unit 228 can also be used to determine a state in which the audio signal is an excessive input. In this case, the threshold voltages Vth1 and Vth2 are determined to be determination levels for excessive inputs. For example, the determination unit 228 can determine that an input is excessive when the determination information COMP_OR is asserted for over a predetermined number of times within a specified period.

When the determination circuit 220 detects an excessive input, the amplifier circuit 200 can output an alarm to the exterior.

### (Variation Example 2)

The determination unit 228 can also be used to determine an amplitude level of the audio signal. In this case, the number of the threshold voltages Vth is increased. For example, when the amplifier circuit 200 includes an automatic gain control (AGC) function, the amplitude level determined by the determination unit 228 can be used for gain control.

### (Variation Example 3)

In the embodiment, the amplifier circuit 200 having one channel is described; however, the amplifier circuit 200 can also be formed by a plurality of channels. In this case, the determination circuit 220 can be shared by the plurality of channels by time division. Accordingly, the circuit area can be inhibited from being increased.

### (Notes)

The present application discloses the following techniques.

### (Item 1)

A differential amplifier circuit for actuating a speaker, comprising:
a first amplifier configured to amplify a positive signal of a differential signal;
a second amplifier configured to amplify a negative signal of the differential signal; and
a determination circuit configured to monitor the positive signal and the negative signal,
wherein the determination circuit includes:
   a comparator;
   a selection circuit configured to selectively supply a first detection signal corresponding to the positive signal and a second detection signal corresponding to the negative signal to a first input of the comparator by time division;
   a voltage source configured to supply a plurality of threshold voltages to a second input of the comparator by time division; and
   a determination unit configured to determine a state of the differential signal based on an output of the comparator.

### (Item 2)

The differential amplifier circuit according to Item 1, wherein the plurality of threshold voltages are in a number of two.

### (Item 3)

The differential amplifier circuit according to Item 2, wherein each of the two threshold voltages is selectable from a plurality of voltage levels.

### (Item 4)

The differential amplifier circuit according to any one of Items 1 to 3, wherein the selection circuit includes:
a first voltage dividing circuit configured to divide the positive signal to generate the first detection signal; and
a second voltage dividing circuit configured to divide the negative signal to generate the second detection signal.

### (Item 5)

The differential amplifier circuit according to Item 4, wherein a voltage dividing ratio of the first voltage dividing circuit and a voltage dividing ratio of the second voltage dividing circuit are switchable.

### (Item 6)

The differential amplifier circuit according to any one of Items 1 to 5, wherein the determination unit is configured to detect a state in which the differential signal contains a DC component.

### (Item 7)

The differential amplifier circuit according to any one of Items 1 to 5, wherein the determination unit is configured to detect a state in which the differential signal is an excessive input.

### (Item 8)

The differential amplifier circuit according to any one of Items 1 to 5, wherein the determination unit is configured to detect an amplitude of the differential signal.

### (Item 9)

The differential amplifier circuit according to any one of Items 1 to 8, wherein the differential amplifier circuit is monolithically integrated on a semiconductor substrate.

Although specific terms are used to describe the embodiments of the present disclosure, it shall be noted that the description merely provides examples for better understanding and are not to be construed as limitations to scope of the present disclosure or the appended claims. The scope of the present disclosure is defined by the appended claims, and therefore implementations, embodiments and variation examples not described herein are also encompassed within the scope of the present disclosure.

1. A differential amplifier circuit for actuating a speaker, comprising:
a first amplifier configured to amplify a positive signal of a differential signal;
a second amplifier configured to amplify a negative signal of the differential signal; and
a determination circuit configured to monitor the positive signal and the negative signal, wherein
the determination circuit includes:
a comparator;
a selection circuit configured to selectively supply a first detection signal corresponding to the positive signal and a second detection signal corresponding to the negative signal to a first input of the comparator by time division;
a voltage source configured to supply a plurality of threshold voltages to a second input of the comparator by time division; and
a determination unit configured to determine a state of the differential signal based on an output of the comparator.

2. The differential amplifier circuit of claim 1, wherein the plurality of threshold voltages are in a number of two.

3. The differential amplifier circuit of claim 2, wherein each of the two threshold voltages is selectable from a plurality of voltage levels.

4. The differential amplifier circuit of claim 1, wherein the selection circuit includes:
a first voltage dividing circuit configured to divide the positive signal to generate the first detection signal; and
a second voltage dividing circuit configured to divide the negative signal to generate the second detection signal.

5. The differential amplifier circuit of claim 2, wherein the selection circuit includes:
a first voltage dividing circuit configured to divide the positive signal to generate the first detection signal; and
a second voltage dividing circuit configured to divide the negative signal to generate the second detection signal.

6. The differential amplifier circuit of claim 3, wherein the selection circuit includes:
a first voltage dividing circuit configured to divide the positive signal to generate the first detection signal; and
a second voltage dividing circuit configured to divide the negative signal to generate the second detection signal.

7. The differential amplifier circuit of claim 4, wherein a voltage dividing ratio of the first voltage dividing circuit and a voltage dividing ratio of the second voltage dividing circuit are switchable.

8. The differential amplifier circuit of claim 1, wherein the determination unit is configured to detect a state in which the differential signal contains a DC component.

9. The differential amplifier circuit of claim 2, wherein the determination unit is configured to detect a state in which the differential signal contains a DC component.

10. The differential amplifier circuit of claim 3, wherein the determination unit is configured to detect a state in which the differential signal contains a DC component.

11. The differential amplifier circuit of claim 1, wherein the determination unit is configured to detect a state in which the differential signal is an excessive input.

12. The differential amplifier circuit of claim 2, wherein the determination unit is configured to detect a state in which the differential signal is an excessive input.

13. The differential amplifier circuit of claim 3, wherein the determination unit is configured to detect a state in which the differential signal is an excessive input.

14. The differential amplifier circuit of claim 1, wherein the determination unit is configured to detect an amplitude of the differential signal.

15. The differential amplifier circuit of claim 2, wherein the determination unit is configured to detect an amplitude of the differential signal.

16. The differential amplifier circuit of claim 3, wherein the determination unit is configured to detect an amplitude of the differential signal.

17. The differential amplifier circuit of claim 1, wherein the differential amplifier circuit is monolithically integrated on a semiconductor substrate.

18. The differential amplifier circuit of claim 2, wherein the differential amplifier circuit is monolithically integrated on a semiconductor substrate.

19. The differential amplifier circuit of claim 3, wherein the differential amplifier circuit is monolithically integrated on a semiconductor substrate.
